(19) United States
(12) Patent Application Publication
(10) Pub. No.: US 2026/0271416 A1
(43) Pub. Date: Sep. 10, 2026

(54) SOLID-STATE IMAGING DEVICE

(71) Applicant: KANEKA CORPORATION, Osaka (JP)

(72) Inventors: Aoi Uozumi, Osaka (JP); Makoto Kutsumizu, Osaka (JP)

(73) Assignee: KANEKA CORPORATION, Osaka (JP)

(21) Appl. No.: 19/554,665

(22) Filed: Mar. 3, 2026

(30) Foreign Application Priority Data
Mar. 6, 2025 (JP) 2025-035242
Dec. 18, 2025 (JP) 2025-264064

(51) Int. Cl. H10F 39/00

(52) U.S. Cl. CPC H10F 39/804; H10F 39/024; H10F 39/806; H10F 39/811

(57) ABSTRACT

A solid-state imaging device includes a solid-state imaging element, a transparent substrate that faces the solid-state imaging element, and a frame disposed between the solid-state imaging element and the transparent substrate and that surrounds an imaging region of the solid-state imaging element. A distance between an end surface of the solid-state imaging element and the imaging region of the solid-state imaging element is 650 μm or less, and a distance between an end surface of the transparent substrate and the imaging region of the solid-state imaging element is 375 μm or more.

### CROSS-REFERENCE TO RELATED APPLICATIONS

This application is based on and claims the benefit of priority from Japanese Patent Application No. 2025-035242, filed on 6 Mar. 2025, and Japanese Patent Application No. 2025-264064, filed on 18 Dec. 2025, the content of which is incorporated herein by reference.

### TECHNICAL FIELD

The present invention relates to a solid-state imaging device.

### BACKGROUND

A solid-state imaging device that is an image sensor, such as a CMOS sensor or a CCD sensor, is known. Such a solid-state imaging device includes, for example, a solid-state imaging element (a semiconductor chip), a transparent substrate disposed so as to face the solid-state imaging element, and a frame disposed between the solid-state imaging element and the transparent substrate so as to surround an imaging region of the solid-state imaging element, and has a hollow structure in which the imaging region of the solid-state imaging element is sealed by the transparent substrate and the frame (see, for example, Patent Document 1).

### Patent Document

Patent Document 1: Japanese Unexamined Patent Application, Publication No. 2014-216475

In such a solid-state imaging device having a hollow structure, when strong light is incident, reflected light (stray light), for example, from a surface of the frame increases, and as a result, optical noise such as flare or ghost occurring in a captured image increases.

Conventionally, a liquid adhesive has been used as the frame of the solid-state imaging device. The liquid adhesive contains a filler or the like in order to obtain thixotropy, and a constriction is generated on a side surface. Therefore, in a frame composed of the liquid adhesive, reflectance at an inner surface is relatively high. As a result, reflected light (stray light) from the inner surface of the frame that is incident on the imaging region of the solid-state imaging element increases, and as a result, optical noise such as flare or ghost derived from the frame occurring in a captured image increases.

The liquid adhesive causes wet spreading. Therefore, in a frame composed of the liquid adhesive, it is necessary to increase a frame region outside the imaging region in the solid-state imaging element and a frame region outside the imaging region in the transparent substrate. As a result, the solid-state imaging element and the transparent substrate become large, and the solid-state imaging device becomes large and expensive.

In this regard, the inventors of the present application have conceived using a resin composition as the frame. With the frame composed of the resin composition, reflectance at the inner surface is lower than that of the frame composed of the liquid adhesive. As a result, with the solid-state imaging device of the comparative example, reflected light (stray light) from the inner surface of the frame, which is incident on the imaging region of the solid-state imaging element, can be reduced as compared with a conventional solid-state imaging device, and as a result, optical noise such as flare or ghost derived from the frame occurring in a captured image can be reduced.

Since the resin composition is formed, for example, by lithography, the resin composition has high dimensional accuracy, and since the resin composition is a semi-cured resin, it is not necessary to consider wet spreading. Therefore, with the frame composed of the resin composition, a frame region outside the imaging region in the solid-state imaging element and a frame region outside the imaging region in the transparent substrate can be reduced as compared with the frame composed of the liquid adhesive. As a result, the solid-state imaging element and the transparent substrate can be reduced in size, and the solid-state imaging device can be reduced in size and cost.

However, when the solid-state imaging device is reduced in size, in particular when the transparent substrate is reduced in size, a distance from an end surface of the transparent substrate to the imaging region of the solid-state imaging element becomes small. As a result, reflected light (stray light) from the end surface of the transparent substrate, which is incident on the imaging region of the solid-state imaging element, increases, and as a result, optical noise such as flare or ghost derived from a transparent substrate edge occurring in a captured image increases.

### SUMMARY

One or more embodiments of the present invention provide a solid-state imaging device that reduces optical noise.

A solid-state imaging device according to the present invention includes: a solid-state imaging element; a transparent substrate disposed so as to face the solid-state imaging element; and a frame disposed between the solid-state imaging element and the transparent substrate so as to surround an imaging region of the solid-state imaging element. A distance between an end surface of the solid-state imaging element and the imaging region of the solid-state imaging element is 650 μm or less, and a distance between an end surface of the transparent substrate and the imaging region of the solid-state imaging element is 375 μm or more.

According to the present invention, in the solid-state imaging device, optical noise such as flare or ghost occurring in a captured image can be reduced.

### BRIEF DESCRIPTION OF THE DRAWINGS

FIG. 1 is a schematic diagram illustrating a solid-state imaging device according to first embodiments, as viewed from a light-receiving surface side;

FIG. 2 is a schematic cross-sectional view of the solid-state imaging device according to the first embodiments, and is a cross-sectional view taken along the line II-II illustrated in FIG. 1;

FIG. 3A is a schematic diagram illustrating a step of obtaining a “transparent substrate with a frame” in a method of manufacturing the solid-state imaging device according to the first embodiments;

FIG. 3B is a schematic diagram illustrating a step of obtaining a “transparent substrate with a frame” in the method of manufacturing the solid-state imaging device according to the first embodiments;

FIG. 3C is a schematic diagram illustrating a step of obtaining a “transparent substrate with a frame” in the method of manufacturing the solid-state imaging device according to the first embodiments;

FIG. 3D is a schematic diagram illustrating a step of obtaining a “transparent substrate with a frame” in the method of manufacturing the solid-state imaging device according to the first embodiments;

FIG. 3E is a schematic diagram illustrating a step of obtaining a “transparent substrate with a frame” in the method of manufacturing the solid-state imaging device according to the first embodiments;

FIG. 3F is a schematic diagram illustrating a step of obtaining a “solid-state imaging element mounted on a wiring substrate” and a step of combining the “solid-state imaging element mounted on the wiring substrate” with the “transparent substrate with a frame” in the method of manufacturing the solid-state imaging device according to the first embodiments;

FIG. 4 is a schematic cross-sectional view of a solid-state imaging device according to Modification Example 1 of the first embodiments;

FIG. 5 is a schematic cross-sectional view of a solid-state imaging device according to Modification Example 2 of the first embodiments;

FIG. 6 is a schematic cross-sectional view of a solid-state imaging device according to second embodiments;

FIG. 7 is a schematic diagram illustrating a method of manufacturing the solid-state imaging device according to the second embodiments;

FIG. 8 is a schematic cross-sectional view of a conventional solid-state imaging device; and

FIG. 9 is a schematic cross-sectional view of a solid-state imaging device of a comparative example.

### DETAILED DESCRIPTION

Hereinafter, an example of embodiments of the present invention will be described with reference to the accompanying drawings. In the drawings, the same or corresponding parts are denoted by the same reference numerals. For convenience, hatching, reference numerals of members, and the like may be omitted in some cases, and in such cases, other drawings are to be referred to.

### First Embodiments

### (Solid-State Imaging Device)

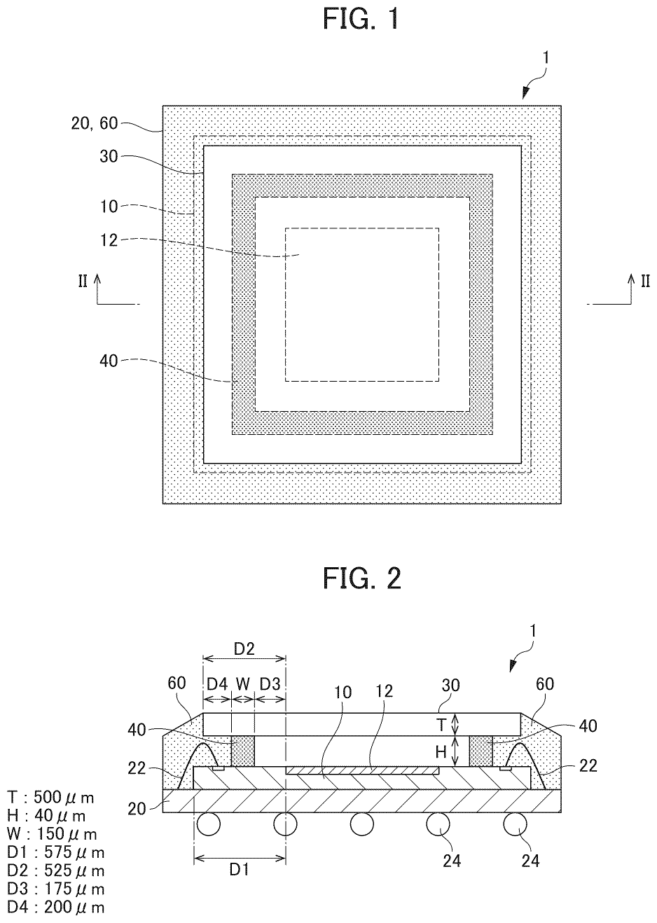

FIG. 1 is a schematic diagram illustrating a solid-state imaging device according to first embodiments, as viewed from a light-receiving surface side, and FIG. 2 is a schematic cross-sectional view of the solid-state imaging device according to the first embodiments, and is a cross-sectional view taken along the line II-II illustrated in FIG. 1. A solid-state imaging device 1 illustrated in FIGS. 1 and 2 is an image sensor such as a CMOS sensor or a CCD sensor, and is a so-called GoC (Glass on Chip) type solid-state imaging device. The solid-state imaging device 1 includes a solid-state imaging element 10, a wiring substrate 20, a transparent substrate 30, and a frame (rib member) 40.

### <Solid-State Imaging Element>

The solid-state imaging element 10 is a semiconductor chip of an image sensor such as a CMOS sensor or a CCD sensor. The semiconductor chip is composed of, for example, a silicon substrate (wafer), and has an imaging region 12 including a plurality of pixels arranged two-dimensionally. Each pixel is composed of, for example, a photodiode. A color filter or a microlens may be disposed on the imaging region 12. The solid-state imaging element 10 is mounted on and bonded to the wiring substrate 20 via, for example, an adhesive.

### <Wiring Substrate>

The wiring substrate 20 is a substrate on which wiring is formed. The wiring substrate 20 and the solid-state imaging element 10 are electrically connected by wiring 22 such as bonding wires. Conductive members 24 such as solder balls are electrically connected to the wiring substrate 20 in order to transmit signals and power between the solid-state imaging element 10 and an external component. The wiring 22 may be covered with a potting resin 60.

Examples of the wiring substrate 20 include organic materials such as polyimide, polyester, ceramic, epoxy, bismaleimide triazine, and phenolic resin, structures obtained by impregnating paper or glass-fiber nonwoven fabric with the organic materials described above and thermally curing the impregnated materials, ceramics such as alumina, aluminum nitride, beryllium oxide, and silicon nitride, and metal substrates. Among these materials, a glass epoxy substrate and a ceramic substrate may be used. A circuit having a metal wiring pattern, metal bumps, metal vias, or metal-film-coated through-holes can be formed on a surface of or inside such an insulating substrate.

As the potting resin 60, a photocurable or thermosetting resin composition, or a resin composition having both photocurability and thermosetting properties, can be used. Examples of the resin composition include curable resins such as an epoxy resin, an acrylic resin, and a silicone resin.

### <Transparent Substrate>

The transparent substrate 30 is disposed so as to face the solid-state imaging element 10, specifically, so as to face one main surface of two main surfaces of the solid-state imaging element 10, the imaging region 12 being formed on the one main surface. As the transparent substrate 30, glass, an acrylic resin, or a transparent plastic such as polycarbonate can be used, and glass may be used from the viewpoint of reliability. The type of glass is not particularly limited, and examples include quartz glass, borosilicate glass, and alkali-free glass.

As necessary, a coating film such as an infrared reflective film (or an infrared cut filter), an antireflection film (AR coating), a protective film, or a reinforcing film can be formed on a surface of the transparent substrate 30. In particular, an antireflection film or an infrared reflective film (or an infrared cut filter) may be used because optical noise in a captured image is reduced. In particular, when the coating film is an antireflection film, the coating film may be a multilayer film including several compounds selected from TiO₂, Nb₂O₅, Ta₂O₅, CaF₂, SiO₂, Al₂O₃, MgS₂, ZrO₂, NiO, and MgF₂.

These coating films can be provided on both surfaces or on one surface of the glass. When the coating films are provided on both surfaces, the types of the coating films may be the same or different. It is also possible to laminate different coating films having the same function on one surface, and it is also possible to laminate different coating films having different functions. The number of laminated layers is not particularly limited, and a multilayer structure having several layers to several tens of layers can be employed.

### <Frame>

The frame (rib member) 40 is disposed between the solid-state imaging element 10 and the transparent substrate 30 so as to surround the imaging region 12 of the solid-state imaging element 10. The frame 40 is bonded to the solid-state imaging element 10 and the transparent substrate 30 by adhesive force of a material of the frame 40.

Examples of the frame 40 include a photocurable resin, a thermosetting resin, or a resin having both photocurability and thermosetting properties, such as an epoxy resin, an acrylic resin, or a silicone resin.

In this manner, in the solid-state imaging device 1, the imaging region 12 of the solid-state imaging element 10 is sealed by the transparent substrate 30 and the frame 40. The solid-state imaging device 1 has a hollow structure having a space above the imaging region 12 of the solid-state imaging element 10.

A resin composition of the frame 40 may include a colorant. Examples of the colorant include an organic pigment, an inorganic pigment, and a dye. From the viewpoints of heat resistance and coloring property, a pigment may be used as the colorant. When a black colored pattern having light-shielding property is formed, a black pigment may be used as the colorant, but the colorant is not limited thereto. In addition, colored patterns other than a black colored pattern, such as a red pattern, a yellow pattern, and a blue pattern, can be used depending on an application.

As the pigment, a pigment that broadly absorbs wavelengths in a visible light region may be used. Among pigments that broadly absorb wavelengths in the visible light region, examples of a black organic pigment include an anthraquinone-based black pigment, a perylene-based black pigment, an azo-based black pigment, and a lactam-based black pigment. Among these pigments, a perylene-based black pigment and a lactam-based black pigment may be used because of excellent light-shielding property. Examples of a black inorganic pigment include carbon black and black low-valence titanium oxynitride. Examples of other inorganic pigments include carbon black, a composite metal oxide pigment, titanium oxide, barium sulfate, lead sulfate, lead yellow, red iron oxide, ultramarine, Prussian blue, chromium oxide, antimony white, zinc sulfide, zinc, manganese violet, cobalt violet, and magnesium carbonate. Examples of the dye include an azo compound, an anthraquinone compound, a perylene compound, a perinone compound, a phthalocyanine compound, a carbonium compound, and an indigoid compound. Examples of pigments used to obtain a colored pattern other than a black colored pattern include chromatic pigments such as red, orange, yellow, green, blue, violet, cyanine, and magenta pigments.

Specific examples of the chromatic pigments include Color Index (C.I.) Pigment Yellow 1, 10, and 83; C.I. Pigment Orange 2, 5, and 13; C.I. Pigment Red 1, 2, and 3; C.I. Pigment Green 7, 10, and 36; and C.I. Pigment Blue 1, 2, and 15. These pigments can be used alone or can be used in various combinations.

Conventionally, a liquid adhesive has been used as a frame of a solid-state imaging device. FIG. 8 is a schematic cross-sectional view of a conventional solid-state imaging device. A conventional solid-state imaging device 1X illustrated in FIG. 8 differs from the solid-state imaging device 1 of one or more embodiments described above in that a liquid adhesive is used as a frame 40X.

In the liquid adhesive, a filler or the like is contained in order to obtain thixotropy, and a constriction is generated on a side surface. Therefore, in the frame 40X composed of the liquid adhesive, reflectance at an inner surface is relatively high. As a result, reflected light (stray light) from the inner surface of the frame 40X, which is incident on the imaging region 12 of a solid-state imaging element 10X, increases, and as a result, optical noise such as flare or ghost derived from the frame occurring in a captured image increases.

The liquid adhesive causes wet spreading (W). Therefore, in the frame 40X composed of the liquid adhesive, it is necessary to increase a frame region (D1) outside the imaging region 12 in the solid-state imaging element 10X and frame regions (D2, D3) outside the imaging region 12 in a transparent substrate 30X. As a result, the solid-state imaging element 10X and the transparent substrate 30X become large, and the solid-state imaging device 1X becomes large and expensive.

For example, dimensions of respective portions of the solid-state imaging device 1X are as follows.

Thickness T of the transparent substrate 30X: 500 μm.
Height H of the frame 40X: 120 μm.
Width W of the frame 40X: 440 μm.
Distance D1 between an end surface of the solid-state imaging element 10X and the imaging region 12 of the solid-state imaging element 10X: 1000 μm.
Distance D2 between an end surface of the transparent substrate 30X and the imaging region 12 of the solid-state imaging element 10X: 725 μm.
Distance D3 between an inner surface of the frame 40X and the imaging region 12 of the solid-state imaging element 10X: 265 μm. Here, the imaging region of the solid-state imaging element may be disposed at a center of the frame or may not be disposed at the center of the frame, and in either case, D1, D2, and D3 indicate the shortest distances among four sides.

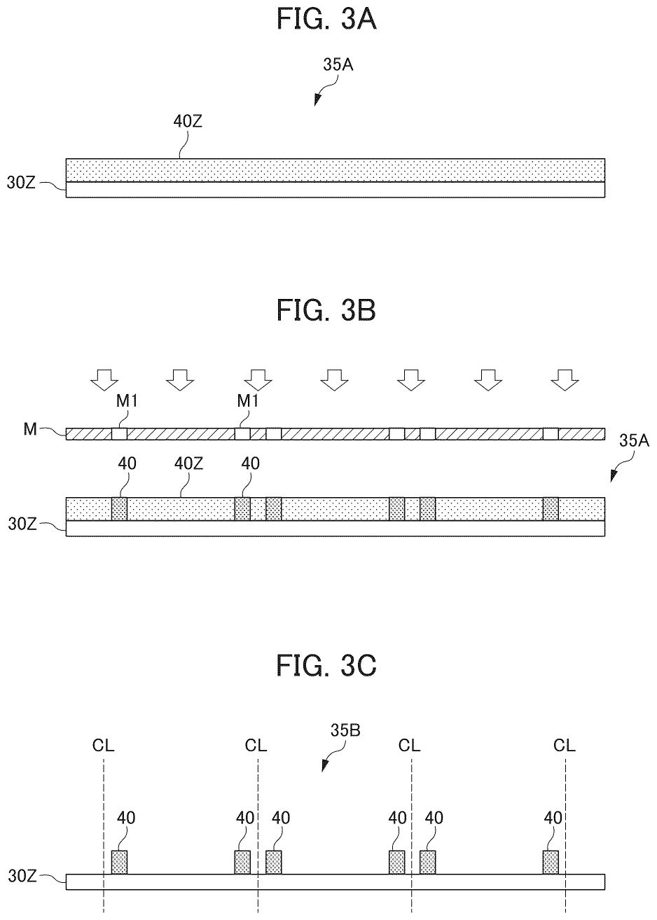

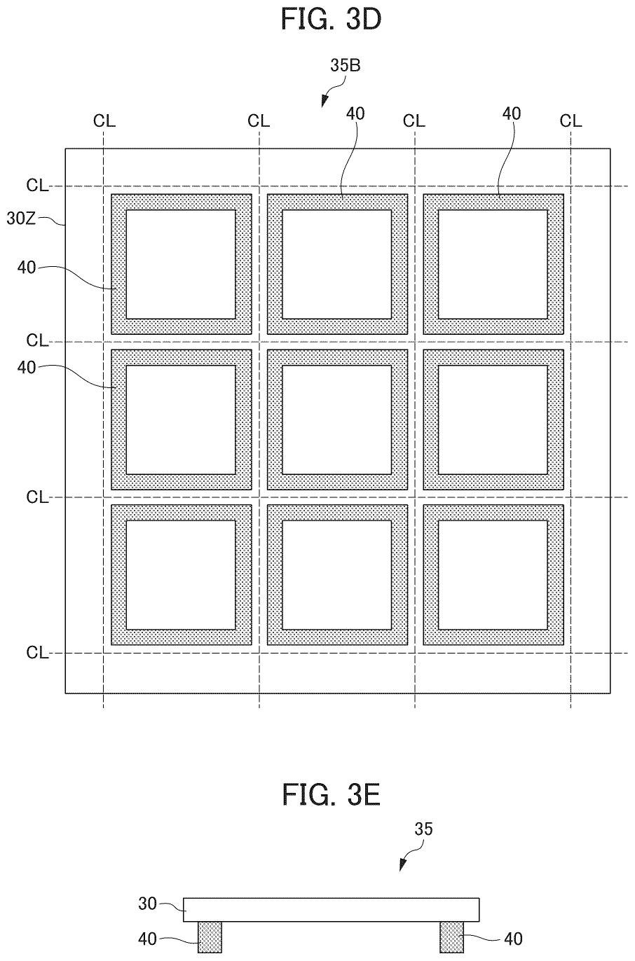

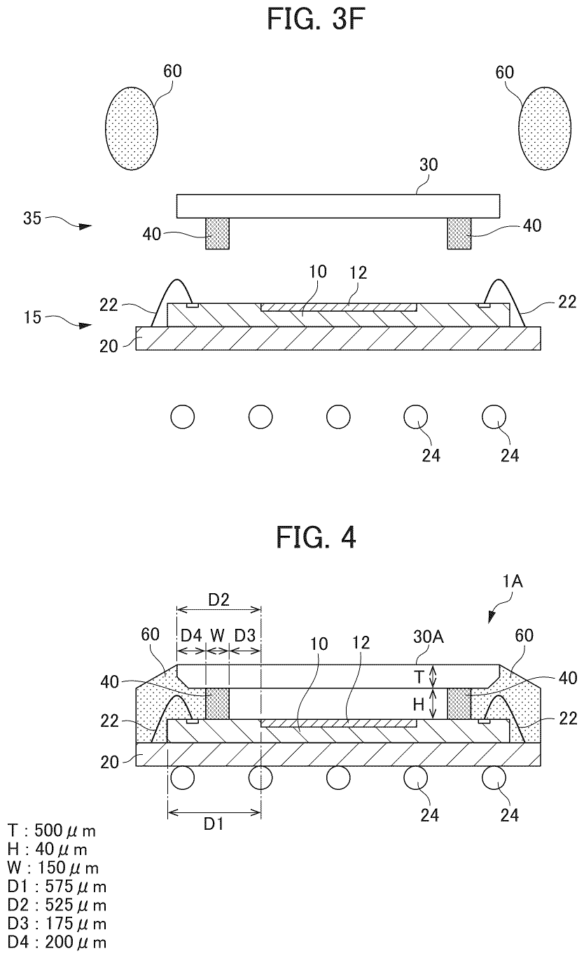

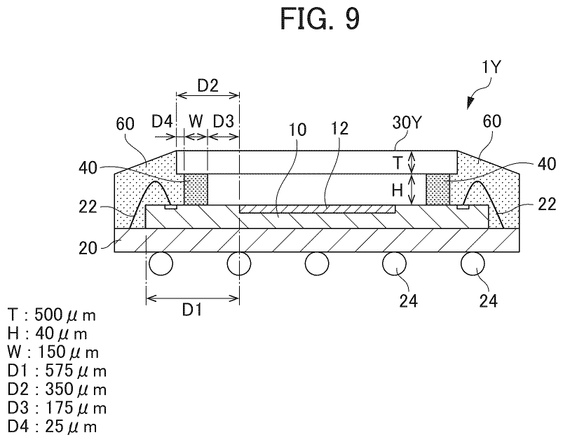

In this regard, the inventors of the present application have conceived using a resin composition as a frame, as illustrated in FIGS. 3A to 3D described later. FIG. 9 is a schematic cross-sectional view of a solid-state imaging device of a comparative example. A solid-state imaging device 1Y of the comparative example illustrated in FIG. 9 differs from the conventional solid-state imaging device 1X described above in that a resin composition is used as a frame 40.

With the frame 40 composed of the resin composition, reflectance at the inner surface is lower than that of the frame 40X composed of the liquid adhesive. As a result, with the solid-state imaging device 1Y of the comparative example, reflected light (stray light) from the inner surface of the frame 40, which is incident on the imaging region 12 of the solid-state imaging element 10, can be reduced as compared with the conventional solid-state imaging device 1X, and as a result, optical noise such as flare or ghost derived from the frame occurring in a captured image can be reduced.

In the resin composition, for example, as illustrated in FIGS. 3A to 3D described later, the frame is formed by lithography, and thus has high dimensional accuracy, and since the resin composition is a semi-cured resin, it is not necessary to consider wet spreading (W). Therefore, with the frame 40 composed of the resin composition, a frame region (D1) outside the imaging region 12 in the solid-state imaging element 10 and frame regions (D2, D3) outside the imaging region 12 in the transparent substrate 30Y can be reduced as compared with the frame 40X composed of the liquid adhesive. For example, when a thickness T of the transparent substrate 30 is approximately 500 μm, a distance D1 between the end surface of the solid-state imaging element 10 and the imaging region 12 of the solid-state imaging element 10 can be smaller than 1000 μm. As a result, the solid-state imaging element 10 and the transparent substrate 30Y can be reduced in size, and the solid-state imaging device 1Y can be reduced in size and cost.

For example, dimensions of respective portions of the solid-state imaging device 1Y are as follows.

Thickness T of the transparent substrate 30Y: 500 μm.
Height H of the frame 40: 40 μm.
Width W of the frame 40: 150 μm.
Distance D1 between the end surface of the solid-state imaging element 10 and the imaging region 12 of the solid-state imaging element 10: 575 μm.
Distance D2 between the end surface of the transparent substrate 30Y and the imaging region 12 of the solid-state imaging element 10: 350 μm.
Distance D3 between the inner surface of the frame 40 and the imaging region 12 of the solid-state imaging element 10: 175 μm. Distance (eaves) D4 between the end surface of the transparent substrate 30 and the outer surface of the frame 40: 25 μm.

However, when the solid-state imaging device 1Y is reduced in size, in particular when the transparent substrate 30Y is reduced in size, a distance (D2) from the end surface of the transparent substrate 30Y to the imaging region 12 of the solid-state imaging element 10 becomes small. As a result, reflected light (stray light) from the end surface of the transparent substrate 30Y, which is incident on the imaging region 12 of the solid-state imaging element 10, increases, and as a result, optical noise such as flare or ghost derived from a transparent substrate edge occurring in a captured image increases.

In this regard, as illustrated in FIG. 2, with the solid-state imaging device 1 of one or more embodiments, the distance D2 between an end surface of the transparent substrate 30 and the imaging region 12 of the solid-state imaging element 10 is increased to be 375 μm or more. In particular, the distance D4 between the end surface of the transparent substrate 30 and the outer surface of the frame 40 is increased to be 50 μm or more (in other words, a width of an eave of the transparent substrate outside the frame of the device is increased). Accordingly, reflected light (stray light) from the end surface of the transparent substrate 30, which is incident on the imaging region 12 of the solid-state imaging element 10, can be reduced, and as a result, optical noise such as flare or ghost derived from a transparent substrate edge occurring in a captured image can be reduced.

For example, dimensions of respective portions of the solid-state imaging device 1 are as follows.

Thickness T of the transparent substrate 30: 500 μm.
Height H of the frame 40: 40 μm.
Width W of the frame 40: 150 μm.
Distance D1 between the end surface of the solid-state imaging element 10 and the imaging region 12 of the solid-state imaging element 10: 575 μm.
Distance D2 between the end surface of the transparent substrate 30 and the imaging region 12 of the solid-state imaging element 10: 525 μm.
Distance D3 between the inner surface of the frame 40 and the imaging region 12 of the solid-state imaging element 10: 175 μm. Distance (eaves) D4 between the end surface of the transparent substrate 30 and an outer surface of the frame 40: 200 μm.

### (Method of Manufacturing Solid-State Imaging Device)

Next, a method of manufacturing the solid-state imaging device according to the first embodiments will be described with reference to FIGS. 3A to 3F. FIGS. 3A to 3E are schematic diagrams illustrating steps of obtaining a “transparent substrate with a frame” in the method of manufacturing the solid-state imaging device according to one or more embodiments, and FIG. 3F is a schematic diagram illustrating a step of obtaining a “solid-state imaging element mounted on a wiring substrate” and a step of combining the “solid-state imaging element mounted on the wiring substrate” with the “transparent substrate with a frame” in the method of manufacturing the solid-state imaging device according to one or more embodiments.

<Step of Obtaining “Transparent Substrate with a Frame”>

First, as illustrated in FIGS. 3A to 3E, a transparent substrate 30 on which the frame 40 is formed, that is, a “transparent substrate with a frame” 35, is manufactured. For example, as illustrated in FIG. 3A, a resin solution is applied to a large-sized transparent substrate 30Z to form a resin film 40Z (a first laminate 35A), and as illustrated in FIG. 3B, a portion 40 in the resin film 40Z is exposed using a photomask M (line pattern M1), and the exposed portion 40 is developed and patterned. Accordingly, as illustrated in FIGS. 3C and 3D, a plurality of frames (ribs, frame-shaped wall bodies obtained by patterning a resin composition) 40 are formed on the large-sized transparent substrate 30Z (a second laminate 35B). Thereafter, the large-sized transparent substrate 30Z is singulated along cut lines CL. Accordingly, as illustrated in FIG. 3E, a plurality of “transparent substrates with frames” 35, in each of which the frame 40 is formed on the transparent substrate 30, are obtained.

### <Step of Obtaining “Solid-State Imaging Element Mounted on a Wiring Substrate”>

As illustrated in FIG. 3F, a solid-state imaging element 10 mounted on a wiring substrate 20, that is, a “solid-state imaging element mounted on a wiring substrate” 15, is manufactured. For example, a plurality of solid-state imaging elements 10 are bonded to a large-sized wiring substrate 20, and after the plurality of solid-state imaging elements 10 are connected to the large-sized wiring substrate 20 by wiring 22 such as bonding wires, the assembly is singulated. Accordingly, the “solid-state imaging element mounted on a wiring substrate” 15 is obtained.

### <Combining Step>

Next, as illustrated in FIG. 3F, the “transparent substrate with a frame” 35 is combined with the “solid-state imaging element mounted on a wiring substrate” 15. For example, the “solid-state imaging element mounted on a wiring substrate” 15 is placed on a stage. The “transparent substrate with a frame” 35 is sucked by a bond head via a collet, and is mounted on the “solid-state imaging element mounted on a wiring substrate” 15.

Then, while heating is performed by the stage (a heating mechanism) or by the stage (a heating mechanism) and the bond head (a heating mechanism), pressure is applied via the collet by the bond head (a pressure mechanism, a load detection sensor), and the “transparent substrate with a frame” 35 is thermocompression-bonded to the “solid-state imaging element mounted on a wiring substrate” 15.

Next, resin is potted onto the wiring 22 such as bonding wires, the wiring 22 such as bonding wires is covered with the potting resin 60, and conductive members 24 such as solder balls are combined with and bonded to the rear surface side of the wiring substrate 20. Accordingly, the solid-state imaging device 1 illustrated in FIG. 2 is obtained.

The order of the singulation step and the combining step may be reversed. For example, after a plurality of “transparent substrates with frames” 35 are respectively combined with a plurality of solid-state imaging elements 10 mounted on a large-sized wiring substrate, singulation may be performed to obtain the solid-state imaging device 1 illustrated in FIG. 2.

As described above, with the solid-state imaging device 1 of the first embodiments, a resin composition is used as the frame 40. Accordingly, reflected light (stray light) from an inner surface of the frame 40, which is incident on the imaging region 12 of the solid-state imaging element 10, can be reduced, and as a result, optical noise such as flare or ghost derived from the frame occurring in a captured image can be reduced.

With the solid-state imaging device 1 of the first embodiments, the resin composition of the frame 40 includes a colorant. Accordingly, reflected light (stray light) from the inner surface of the frame 40, which is incident on the imaging region 12 of the solid-state imaging element 10, can be further reduced, and as a result, optical noise such as flare or ghost derived from the frame occurring in a captured image can be further reduced.

With the frame 40 composed of the resin composition, it is not necessary to consider wet spreading (W) unlike the frame 40X composed of the liquid adhesive, and thus the frame region (D1) outside the imaging region 12 in the solid-state imaging element 10 can be reduced. For example, when the thickness T of the transparent substrate 30 is approximately 500 μm, the distance D1 between the end surface of the solid-state imaging element 10 and the imaging region 12 of the solid-state imaging element 10 can be smaller than 1000 μm. As a result, the solid-state imaging element 10, which is a relatively expensive semiconductor chip, can be reduced in size, and the solid-state imaging device 1 can be reduced in size and cost.

Further, with the solid-state imaging device 1 of the first embodiments, the distance D2 between the end surface of the transparent substrate 30 and the imaging region 12 of the solid-state imaging element 10 is 375 μm or more, and the distance D4 between the end surface of the transparent substrate 30 and the outer surface of the frame 40 is 50 μm or more. Accordingly, reflected light (stray light) from the end surface of the transparent substrate 30, which is incident on the imaging region 12 of the solid-state imaging element 10, can be reduced, and as a result, optical noise such as flare or ghost derived from a transparent substrate edge occurring in a captured image can be reduced.

The distance D4 between the end surface of the transparent substrate 30 and the outer surface of the frame 40 may be 50 μm or more and 300 μm or less, or may be 50 μm or more and 150 μm or less, and further may be 50 μm or more and 75 μm or less. For example, W+D3 is 300 μm to 350 μm (W is approximately 50 μm to 250 μm, and D3 is approximately 100 μm to 300 μm). For example, when D4 is 50 μm or more and 300 μm or less, ranges of respective values may be as follows.

Thickness T of the transparent substrate 30: 500 μm.
Height H of the frame 40: 40 μm.
Width W of the frame 40: 150 μm.
Distance (eaves) D4 between the end surface of the transparent substrate 30 and the outer surface of the frame 40: 50 μm or more and 300 μm or less.
Distance D2 between the end surface of the transparent substrate 30 and the imaging region 12 of the solid-state imaging element 10: 375 μm or more and 625 μm or less.

Meanwhile, when the length of the transparent substrate 30 is increased, in particular when the eave under the transparent substrate 30 outside the frame 40 is increased, the transparent substrate 30 may come into contact with the wiring 22 (bonding wires). In addition, the resin 60 may be less likely to enter under the eave of the transparent substrate 30 outside the frame 40.

In this regard, the distance D4 between the end surface of the transparent substrate 30 and the outer surface of the frame 40 may be 150 μm or less. Accordingly, the resin 60 can be more easily introduced under the eave of the transparent substrate 30 outside the frame 40. In this case, ranges of respective values may be as follows.

Thickness T of the transparent substrate 30: 500 μm.
Height H of the frame 40: 40 μm.
Width W of the frame 40: 150 μm.
Distance (eaves) D4 between the end surface of the transparent substrate 30 and the outer surface of the frame 40: 50 μm or more and 150 μm or less.
Distance D2 between the end surface of the transparent substrate 30 and the imaging region 12 of the solid-state imaging element 10: 375 μm or more and 475 μm or less.

The distance D4 between the end surface of the transparent substrate 30 and the outer surface of the frame 40 may be 75 μm or less. Accordingly, the resin 60 can be more easily introduced under the eave of the transparent substrate 30 outside the frame 40, and contact between the transparent substrate 30 and wiring 22 (bonding wires) can be further reduced. In this case, ranges of respective values may be as follows.

Thickness T of the transparent substrate 30: 500 μm.
Height H of the frame 40: 40 μm.
Width W of the frame 40: 150 μm.
Distance (eaves) D4 between the end surface of the transparent substrate 30 and the outer surface of the frame 40: 50 μm or more and 75 μm or less.
Distance D2 between the end surface of the transparent substrate 30 and the imaging region 12 of the solid-state imaging element 10: 375 μm or more and 400 μm or less.

### Modification Example 1

As described above, when the length of the transparent substrate 30 is increased, in particular when the eave under the transparent substrate 30 outside the frame 40 is increased, the transparent substrate 30 may come into contact with the wiring 22 (bonding wires). In addition, the resin 60 may be less likely to enter under the eave of the transparent substrate 30 outside the frame 40.

In this regard, the inventors of the present application have conceived cutting away a peripheral corner portion on a solid-state imaging element side of a transparent substrate. FIG. 4 is a schematic cross-sectional view of a solid-state imaging device according to Modification Example 1 of the first embodiments. As illustrated in FIG. 4, a solid-state imaging device 1A according to Modification Example 1 differs from the solid-state imaging device 1 illustrated in FIG. 2 in that the solid-state imaging device 1A includes a transparent substrate 30A instead of the transparent substrate 30.

The transparent substrate 30A differs from the transparent substrate 30 described above in that a peripheral corner portion on a solid-state imaging element 10 side is subjected to bevel processing so that the peripheral corner portion on the solid-state imaging element 10 side is shaved, thereby having a diagonally cut notch at the peripheral corner portion on the solid-state imaging element 10 side. A method of forming the notch is not limited to bevel processing, and various cutting processes and other various processes may be applied. Accordingly, in the transparent substrate 30A, the thickness of the peripheral corner portion is smaller than the thickness of the central planar portion.

With the solid-state imaging device 1A of Modification Example 1, contact between the transparent substrate 30A and wiring (bonding wires) 22 can be reduced. In addition, the resin 60 can be more easily introduced under the eave of the transparent substrate 30 outside the frame 40.

### Modification Example 2

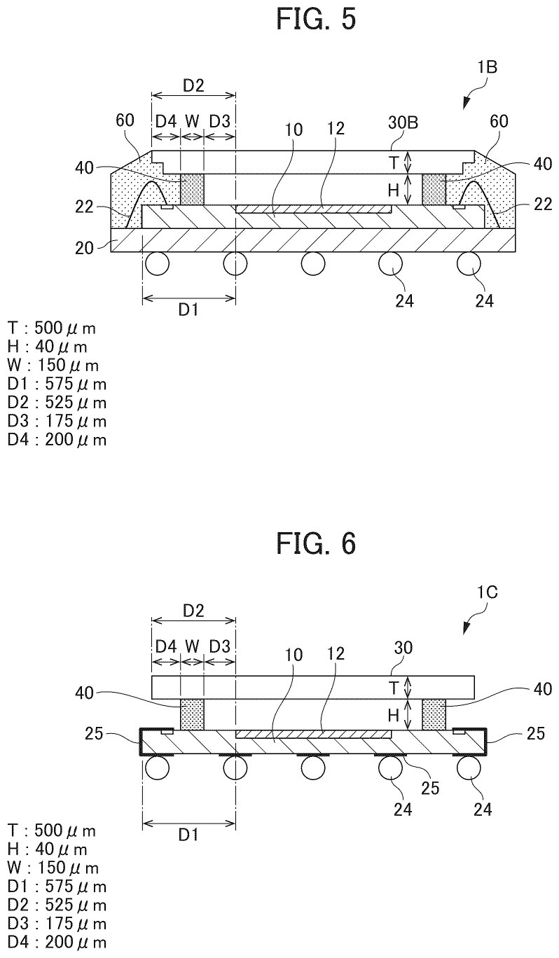

FIG. 5 is a schematic cross-sectional view of a solid-state imaging device according to Modification Example 2 of the first embodiments. As illustrated in FIG. 5, a solid-state imaging device 1B according to Modification Example 2 differs from the solid-state imaging device 1 illustrated in FIG. 2 in that the solid-state imaging device 1B includes a transparent substrate 30B instead of the transparent substrate 30.

The transparent substrate 30B differs from the transparent substrate 30 described above in that a peripheral corner portion on the solid-state imaging element 10 side is subjected to step-cut processing so that the peripheral corner portion on the solid-state imaging element 10 side is shaved, thereby having a step-shaped notch at the peripheral corner portion on the solid-state imaging element 10 side. A method of forming the notch is not limited to bevel processing, and various cutting processes and other various processes may be applied. Accordingly, in the transparent substrate 30B, the thickness of the peripheral corner portion is smaller than the thickness of the central planar portion.

Also in the solid-state imaging device 1B of Modification Example 2, contact between the transparent substrate 30B and wiring (bonding wires) 22 can be reduced. In addition, the resin 60 can be more easily introduced under the eave of the transparent substrate 30 outside the frame 40.

### Second Embodiments

### (Solid-State Imaging Device)

FIG. 6 is a schematic cross-sectional view of a solid-state imaging device according to second embodiments. A solid-state imaging device 1C illustrated in FIG. 6 is a so-called CSP (Chip Size Package) type solid-state imaging device. The solid-state imaging device 1C of the second embodiments differs from the solid-state imaging device 1 of the first embodiments described above in that the solid-state imaging device 1C does not include the wiring substrate 20 and directly performs electrical connection with an external component by electrodes such as pads formed on a rear surface of the solid-state imaging element 10.

Specifically, the transparent substrate 30 is disposed so as to face the solid-state imaging element 10. The frame (rib member) 40 is disposed between the solid-state imaging element 10 and the transparent substrate 30 so as to surround the imaging region 12 of the solid-state imaging element 10. Electrodes 25 such as pads are formed on the rear surface of the solid-state imaging element 10, and conductive members 24 such as solder balls are electrically connected to the electrodes 25 such as pads.

### (Method of Manufacturing Solid-State Imaging Device)

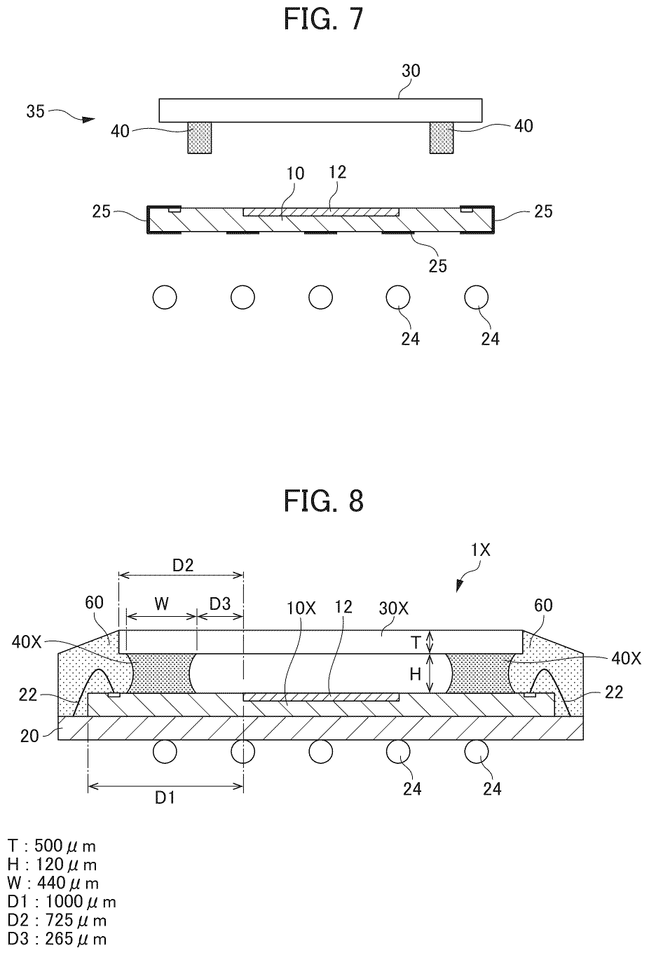

Next, a method of manufacturing the solid-state imaging device according to the second embodiments will be described with reference to FIG. 7. FIG. 7 is a schematic diagram illustrating the method of manufacturing the solid-state imaging device according to the second embodiments.

First, as illustrated in FIG. 7, similarly to the above description, a transparent substrate 30 on which the frame 40 is formed, that is, a “transparent substrate with a frame” 35, is manufactured. A solid-state imaging element 10, in which electrodes 25 such as pads are formed on a rear surface side, is prepared.

Next, the “transparent substrate with a frame” 35 is combined with the solid-state imaging element 10. For example, the solid-state imaging element 10 is placed on a stage. The “transparent substrate with a frame” 35 is sucked by a bond head via a collet, and is mounted on the solid-state imaging element 10.

Then, while heating is performed by the stage (a heating mechanism) or by the stage (a heating mechanism) and the bond head (a heating mechanism), pressure is applied via the collet by the bond head (a pressure mechanism, a load detection sensor), and the “transparent substrate with a frame” 35 is thermocompression-bonded to the solid-state imaging element 10.

Next, conductive members 24 such as solder balls are combined with and bonded to the electrodes 25 such as pads on the rear surface side of the solid-state imaging element 10. Accordingly, the solid-state imaging device 1C illustrated in FIG. 6 is obtained.

Alternatively, a manufacturing method may be employed in which a large-sized solid-state imaging element before singulation and a large-sized transparent substrate with a frame before singulation are bonded to each other, and then singulated to obtain a solid-state imaging device.

Also in the solid-state imaging device 1C of the second embodiments, a resin composition is used as the frame 40. Accordingly, reflected light (stray light) from an inner surface of the frame 40, which is incident on the imaging region 12 of the solid-state imaging element 10, can be reduced, and as a result, optical noise such as flare or ghost derived from the frame occurring in a captured image can be reduced.

With the frame 40 composed of the resin composition, it is not necessary to consider wet spreading (W) unlike the frame 40X composed of the liquid adhesive, and thus the frame region (D1) outside the imaging region 12 in the solid-state imaging element 10 can be reduced. For example, when the thickness T of the transparent substrate 30 is approximately 500 μm, the distance D1 between the end surface of the solid-state imaging element 10 and the imaging region 12 of the solid-state imaging element 10 can be smaller than 1000 μm. As a result, the solid-state imaging element 10, which is a relatively expensive semiconductor chip, can be reduced in size, and the solid-state imaging device 1 can be reduced in size and cost.

Further, also in the solid-state imaging device 1C of the second embodiments, the distance D2 between the end surface of the transparent substrate 30 and the imaging region 12 of the solid-state imaging element 10 is 375 μm or more, and the distance D4 between the end surface of the transparent substrate 30 and the outer surface of the frame 40 is 50 μm or more. Accordingly, reflected light (stray light) from the end surface of the transparent substrate 30, which is incident on the imaging region 12 of the solid-state imaging element 10, can be reduced, and as a result, optical noise such as flare or ghost derived from a transparent substrate edge occurring in a captured image can be reduced.

Although embodiments of the present invention have been described above, the present invention is not limited to the embodiments described above, and various modifications and variations are possible. For example, in the embodiments described above, a so-called GoC (Glass on Chip) type solid-state imaging device (FIG. 2) and a so-called CSP (Chip Size Package) type solid-state imaging device (FIG. 4) have been illustrated as examples. However, the features of the present invention are not limited thereto, and the present invention is applicable to various types of solid-state imaging devices.

### EXAMPLES

Hereinafter, the present invention will be specifically described based on examples, but the present invention is not limited to the following examples.

### Example 1

As described below, the solid-state imaging device 1 illustrated in FIGS. 1 and 2 was manufactured in accordance with the manufacturing method illustrated in FIGS. 3A to 3F.

(Transparent Substrate with a Frame)

### <Solution A Containing Resin A>

A dissolved material was obtained by dissolving 40 g of diallyl isocyanurate and 29 g of diallyl monomethyl isocyanurate in 264 g of dioxane. Next, 143 μL of a xylene solution of a platinum vinyl siloxane complex (a platinum vinyl siloxane complex containing 3 mass % of platinum, manufactured by Umicore Precious Metals Japan, Pt-VTSC-3X) was added to the dissolved material to obtain Solution 1.

A solution 2 was obtained by dissolving 88 g of 1,3,5,7-tetrahydrogen-1,3,5,7-tetramethylcyclotetrasiloxane in 176 g of toluene. Then, while the solution 2 was heated to 105° C. under a nitrogen atmosphere (containing 3% oxygen), the solution 1 was added dropwise to the solution 2 over 3 hours, and the state was maintained for 30 minutes after completion of the dropwise addition to obtain a solution 3. When a reaction rate of alkenyl groups of a compound contained in the solution 3 was measured by 1H-NMR, the reaction rate was 95% or more.

A solution 4 was obtained by dissolving 62 g of 1-vinyl-3,4-epoxycyclohexane in 62 g of toluene. Then, while the solution 3 was heated to 105° C. under a nitrogen atmosphere (containing 3% oxygen), the solution 4 was added dropwise to the solution 3 over 1 hour, and the state was maintained for 30 minutes after completion of the dropwise addition to obtain a solution 5. After confirming that a reaction rate of alkenyl groups of a compound contained in the solution 5 was 95% or more, the solution 5 was cooled to terminate the reaction.

Next, solvents (toluene and dioxane) were removed from the solution 5 under reduced pressure to obtain a solid content, and propylene glycol 1-monomethyl ether 2-acetate was added to the solid content to obtain a solution A containing 70 mass % of resin A.

### <Other Materials>

As materials for a curable composition, in addition to the solution A described above, the following materials were prepared.
Radical generator (2,2-dimethoxy-2-phenylacetophenone) (Omnirad 651, IGM Resins B.V.).
Trifunctional acrylic compound (tris-(2-acryloxyethyl) isocyanurate) (A-9300, Shin-Nakamura Chemical Co., Ltd.).
Colorant (carbon black MA100, manufactured by Mitsubishi Chemical Corporation).

### <Curable Composition>

A curable composition was prepared by mixing 100 g of the solution A, 0.07 g of Omnirad 651, 35 g of A-9300, and 0.175 g of carbon black MA100.

Next, as illustrated in FIG. 3A, the curable composition described above was applied onto a surface of a large-sized glass substrate 30Z having dimensions of 100 mm×100 mm×0.5 mm by a spin coater to form a coating film 40Z on the large-sized glass substrate 30Z, thereby obtaining a first laminate 35A. Next, the first laminate 35A was heated for 10 minutes on a hot plate heated to 125° C. to obtain the large-sized glass substrate 30Z, on which a thin film 40Z having a thickness of 40 μm was formed.

Next, as illustrated in FIG. 3B, using an exposure apparatus (manual exposure apparatus, manufactured by Dainippon Scientific Co., Ltd.) (lamp: high-pressure mercury lamp), through a photomask M on which a line pattern M1 was formed in a lattice shape, a portion 40 of the coating film 40Z of the heated first laminate 35A was exposed by soft-contact exposure with an optimum integrated light amount. Next, the exposed first laminate 35A was heated for 10 minutes on a hot plate heated to 95° C. Accordingly, the exposed portion 40 of the coating film 40Z was brought into a semi-cured state.

Next, the first laminate 35A that had been left to stand for 1 minute was immersed for 60 seconds in an alkaline developer (alkaline component: TMAH; TMAH content: 2.38 mass %). Thereafter, the first laminate 35A immersed in the alkaline developer was washed with water for 30 seconds. Next, moisture on a surface of the washed first laminate 35A was removed with compressed air. Accordingly, as illustrated in FIGS. 3C and 3D, the thin film 40Z on the large-sized glass substrate 30Z was patterned, and the large-sized glass substrate 30Z provided with the frame 40 (rib member), which is a semi-cured frame-shaped (rectangular tubular) wall body, was obtained as a second laminate 35B.

Next, among surfaces of the second laminate 35B, a dicing film was temporarily bonded to a surface on which the frame 40 was not provided, and then the large-sized glass substrate 30Z was cut along cut lines CL between the frames 40 with a dicing blade into pieces having a size of 9 mm×6 mm. Thereafter, the dicing film was peeled off to obtain singulated “transparent substrates with frames” 35 illustrated in FIG. 3E (the frame 40 having a height of 40 μm and a width of 150 μm).

### (Solid-State Imaging Element Mounted on a Wiring Substrate)

As illustrated in FIG. 3F, a plurality of solid-state imaging elements 10 were bonded to a large-sized wiring substrate 20, and the plurality of solid-state imaging elements 10 were connected to the large-sized wiring substrate 20Z by wiring 22 that are bonding wires, followed by singulation. Accordingly, a “solid-state imaging element mounted on a wiring substrate” 15 was obtained.

### (Bonding)

Next, as illustrated in FIG. 3F, using a bonding machine (“CB-505” manufactured by Athlete FA Co., Ltd.), a “transparent substrate with a frame” 35 was laminated on the “solid-state imaging element mounted on a wiring substrate” 15. Specifically, a collet was installed on an upper bond head, and then the “transparent substrate with a frame” 35 was placed such that a surface on which the frame 40 was not provided was in contact with the collet.

Thereafter, the bond head and the stage were heated to 100° C., and were brought close to the “solid-state imaging element mounted on a wiring substrate” 15. When a load detection sensor attached to the bond head indicated 5 N, the state was maintained for 10 seconds, and suction of the “transparent substrate with a frame” 35 by the collet was released. Next, a laminate of the “solid-state imaging element mounted on a wiring substrate” 15 and the “transparent substrate with a frame” 35 was heated in an oven at a temperature of 200° C. for 2 hours to bond the “solid-state imaging element mounted on a wiring substrate” 15 and the “transparent substrate with a frame” 35.

Next, resin was potted onto wiring 22 such as bonding wires, the wiring 22 such as bonding wires was covered with the potting resin 60, and conductive members 24 such as solder balls were combined with and bonded to a rear surface side of the wiring substrate 20. Accordingly, as illustrated in FIGS. 1 and 2, the solid-state imaging device 1 of Example 1, in which the “transparent substrate with a frame” 35 was bonded to the “solid-state imaging element mounted on a wiring substrate” 15, was obtained.

Main configurations of the solid-state imaging device 1 of Example 1 are as follows and as shown in Tables 1 and 2.

### <Configurations of Solid-State Imaging Device>

Material of the frame: the resin composition described above.
Thickness T of the transparent substrate 30: 500 μm.
Height H of the frame 40: 40 μm.
Width W of the frame 40: 150 μm.
Distance D1 between the end surface of the solid-state imaging element 10 and the imaging region 12 of the solid-state imaging element 10: 575 μm.
Distance D2 between the end surface of the transparent substrate 30 and the imaging region 12 of the solid-state imaging element 10: 375 μm.
Distance D3 between the inner surface of the frame 40 and the imaging region 12 of the solid-state imaging element 10: 175 μm.
Distance (eaves) D4 between the end surface of the transparent substrate 30 and an outer surface of the frame 40: 50 μm.
Transparent substrate edge processing: none.
Frame color: black.

### Examples 2 to 6

When manufacturing the “transparent substrate with a frame” 35, the procedures were performed in the same manner as in Example 1 except for a size of the transparent substrate 30. Examples 2 to 6 differ from Example 1 in values of D2 and D4. Main differences in configurations of the solid-state imaging devices of Examples 2 to 6 are as follows and as shown in Tables 1 and 2.

### Example 2

In Example 2, D4 is larger than that in Example 1, and as a result, D2 is larger.

Distance D2 between the end surface of the transparent substrate 30 and the imaging region 12 of the solid-state imaging element 10: 400 μm.
Distance (eaves) D4 between the end surface of the transparent substrate 30 and an outer surface of the frame 40: 75 μm.

### Example 3

In Example 3, D4 is further larger than that in Example 2, and as a result, D2 is further larger.

Distance D2 between the end surface of the transparent substrate 30 and the imaging region 12 of the solid-state imaging element 10: 425 μm.
Distance (eaves) D4 between the end surface of the transparent substrate 30 and an outer surface of the frame 40: 100 μm.

### Example 4

In Example 4, D4 is further larger than that in Example 3, and as a result, D2 is further larger.

Distance D2 between the end surface of the transparent substrate 30 and the imaging region 12 of the solid-state imaging element 10: 475 μm.
Distance (eaves) D4 between the end surface of the transparent substrate 30 and an outer surface of the frame 40: 150 μm.

### Example 5

In Example 5, D4 is further larger than that in Example 4, and as a result, D2 is further larger.

Distance D2 between the end surface of the transparent substrate 30 and the imaging region 12 of the solid-state imaging element 10: 525 μm.
Distance (eaves) D4 between the end surface of the transparent substrate 30 and an outer surface of the frame 40: 200 μm.

### Example 6

In Example 6, D4 is further larger than that in Example 5, and as a result, D2 is further larger.

Distance D2 between the end surface of the transparent substrate 30 and the imaging region 12 of the solid-state imaging element 10: 625 μm.
Distance (eaves) D4 between the end surface of the transparent substrate 30 and an outer surface of the frame 40: 300 μm.

### Example 7

When manufacturing the “transparent substrate with a frame” 35, the procedures were performed in the same manner as in Example 3 except that edge processing was performed on the transparent substrate 30. Example 7 differs from Example 3 in that, as illustrated in FIG. 4, bevel processing was performed on a peripheral corner portion on the solid-state imaging element 10 side of the transparent substrate 30 to provide a diagonally cut notch. Main differences in configurations of the solid-state imaging device of Example 7 are as follows.

Transparent substrate edge processing: bevel processing performed, diagonally cut notch.
Transparent substrate edge processing depth: 10 μm.

### Example 8

When manufacturing the “transparent substrate with a frame” 35, the procedures were performed in the same manner as in Example 4 except that edge processing was performed on the transparent substrate 30. Example 8 differs from Example 4 in that, as illustrated in FIG. 4, bevel processing was performed on a peripheral corner portion on the solid-state imaging element 10 side of the transparent substrate 30 to provide a diagonally cut notch. Main differences in configurations of the solid-state imaging device of Example 8 are as follows.

Transparent substrate edge processing: bevel processing performed, diagonally cut notch.
Transparent substrate edge processing depth: 50 μm.

### Example 9

When manufacturing the “transparent substrate with a frame” 35, the procedures were performed in the same manner as in Example 3 except that edge processing was performed on the transparent substrate 30. Example 9 differs from Example 3 in that, as illustrated in FIG. 5, step-cut processing was performed on a peripheral corner portion on the solid-state imaging element 10 side of the transparent substrate 30 to provide a step-shaped notch. Main differences in configurations of the solid-state imaging device of Example 9 are as follows.

Transparent substrate edge processing: step-cut processing performed, step-shaped notch.
Transparent substrate edge processing depth: 10 μm.

### Example 10

When manufacturing the “transparent substrate with a frame” 35, the procedures were performed in the same manner as in Example 7 except that a colorant was not used as a material of the curable composition of the frame 40. Example 10 differs from Example 7 in frame color. Main differences in configurations of the solid-state imaging device of Example 10 are as follows.

Frame color: transparent.

### Comparative Example 1

A conventional solid-state imaging device illustrated in FIG. 8 was manufactured as Comparative Example 1. Main configurations of the solid-state imaging device of Comparative Example 1 are as follows.

### <Configurations of Solid-State Imaging Device>

Material of the frame: a liquid adhesive instead of the resin composition described above.
Thickness T of the transparent substrate 30: 500 μm.
Height H of the frame 40: 120 μm.
Width W of the frame 40: 440 μm.
Distance D1 between an end surface of the solid-state imaging element 10 and the imaging region 12 of the solid-state imaging element 10: 1000 μm.
Distance D2 between an end surface of the transparent substrate 30 and the imaging region 12 of the solid-state imaging element 10: 725 μm.
Distance D3 between an inner surface of the frame 40 and the imaging region 12 of the solid-state imaging element 10: 265 μm.
Distance (eaves) D4 between an end surface of the transparent substrate 30 and an outer surface of the frame 40: 25 μm.
Transparent substrate edge processing: none.
Frame color: transparent.

### Comparative Example 2

A solid-state imaging device of a comparative example illustrated in FIG. 9 was manufactured as Comparative Example 2. Main configurations of the solid-state imaging device of Comparative Example 2 are as follows.

### <Configurations of Solid-State Imaging Device>

Material of the frame: the resin composition described above.
Thickness T of the transparent substrate 30: 500 μm.
Height H of the frame 40: 40 μm.
Width W of the frame 40: 150 μm.
Distance D1 between an end surface of the solid-state imaging element 10 and the imaging region 12 of the solid-state imaging element 10: 575 μm.
Distance D2 between an end surface of the transparent substrate 30Y and the imaging region 12 of the solid-state imaging element 10: 350 μm.
Distance D3 between an inner surface of the frame 40 and the imaging region 12 of the solid-state imaging element 10: 175 μm.
Distance (eaves) D4 between an end surface of the transparent substrate 30Y and an outer surface of the frame 40: 25 μm.
Transparent substrate edge processing: none.
Frame color: black.

### (Evaluation)

Evaluation methods for respective evaluation items will be described.

### <Frame-Derived Flare, Transparent-Substrate-Edge-Derived Flare>

For a solid-state imaging device to be evaluated, the number of pixels exceeding a predetermined threshold (hereinafter referred to as “number of abnormal pixels”) was confirmed using a ghost flare evaluation system (“GCS-2T” manufactured by Tsubosaka Electric Co., Ltd.), and calculated according to the following formula.

(Number of abnormal pixels/total number of pixels)×100=frame-derived flare (%) or transparent-substrate-edge-derived flare (%).

### <Contact Between Wiring and Transparent Substrate>

In a cross section near wiring 22 of the solid-state imaging element 10 and the transparent substrate 30, contact between the wiring 22 and the transparent substrate was confirmed using a desktop microscope (“Miniscope TM3030Plus” manufactured by Hitachi High-Tech Corporation, observation magnification: 800×).

### <Fillability of Potting Resin>

In a cross section of the potting resin 60, fillability of the potting resin 60 under the eave of the transparent substrate 30 outside the frame 40 was confirmed using a desktop microscope (“Miniscope TM3030Plus” manufactured by Hitachi High-Tech Corporation, observation magnification: 800×). A case where the potting resin 60 was filled without bubbles under the eave of the transparent substrate 30 outside the frame 40 was rated as “A,” and a case where bubbles were present and the potting resin 60 was not filled under the eave of the transparent substrate 30 outside the frame 40 was rated as “B.”

Evaluation results of the respective evaluation items are as shown in Tables 1 and 2 below.

TABLE 1

| | | Difference in Eave Length | | | | | |
|---|---|---|---|---|---|---|---|
| | | Example 1 | Example 2 | Example 3 | Example 4 | Example 5 | Example 6 |
| D2 (μm) | | 375 | 400 | 425 | 475 | 525 | 625 |
| D1 (μm) | | 575 | 575 | 575 | 575 | 575 | 575 |
| D4 (μm) | | 50 | 75 | 100 | 150 | 200 | 300 |
| Transparent substrate | | None | None | None | None | None | None |
| edge processing | | | | | | | |
| Transparent substrate | | 0 | 0 | 0 | 0 | 0 | 0 |
| edge processing depth (μm) | | | | | | | |
| Frame height H (μm) | | 40 | 40 | 40 | 40 | 40 | 40 |
| Frame color | | Black | Black | Black | Black | Black | Black |
| Evaluation | Frame-derived flare (%) | 0.01 | 0.01 | 0.01 | 0.01 | 0.01 | 0.01 |
| results | Transparent-substrate- | 0.2 | 0.15 | 0.05 | 0 | 0 | 0 |
| | edge-derived flare (%) | | | | | | |
| | Contact between wire and | None | None | Present | Present | Present | Present |
| | transparent substrate | | | | | | |
| | Fillability of potting resin | A | A | A | A | B | B |

TABLE 2

| | | | | | | Comparative Examples | |
|---|---|---|---|---|---|---|---|
| | | Glass Edge Shape | | | [symbol] Transparenc [symbol] | Comparative | Comparative |
| | | Example 7 | Example 8 | Example 9 | Example 10 | Examples 1 | Examples 2 |
| D2 (μm) | | 425 | 475 | 425 | 425 | 725 | 350 |
| D1 (μm) | | 575 | 575 | 575 | 575 | 1000 | 575 |
| D4 (μm) | | 100 | 150 | 100 | 100 | 25 | 25 |
| Transparent substrate | | Diagonal | Diagonal | Step-shaped | Diagonal | None | None |
| edge processing | | | | | | | |
| Transparent substrate | | 10 | 50 | 10 | 10 | 0 | 0 |
| edge processing depth (μm) | | | | | | | |
| Frame height H (μm) | | 40 | 40 | 40 | 40 | 120 | 40 |
| Frame color | | Black | Black | Black | Transparent | Transparent | Black |
| Evaluation | Frame-derived flare (%) | 0.01 | 0.01 | 0.01 | 0.05 | 1.00 | 0.01 |
| results | Transparent-substrate- | 0.05 | 0 | 0.05 | 0.08 | 0 | 0.3 |
| | edge-derived flare (%) | | | | | | |
| | Contact between wire and | None | None | None | None | None | None |
| | transparent substrate | | | | | | |
| | Fillability of potting resin | A | A | A | A | A | A |

[symbol]

indicates data missing or illegible when filed

From results of Comparative Example 2 and Examples 1 to 6, when the distance D1 between the end surface of the solid-state imaging element 10 and the imaging region 12 of the solid-state imaging element 10 is 575 μm, transparent-substrate-edge-derived flare improves as the distance D2 between the end surface of the transparent substrate 30 and the imaging region 12 of the solid-state imaging element 10 becomes longer, and as the distance (eaves) D4 between the end surface of the transparent substrate 30 and an outer surface of the frame 40 becomes longer. Among these cases, when the distance D2 between the end surface of the transparent substrate 30 and the imaging region 12 of the solid-state imaging element 10 is 475 μm or more and the distance (eaves) D4 between the end surface of the transparent substrate 30 and the outer surface of the frame 40 is 150 μm or more, transparent-substrate-edge-derived flare becomes 0%. This is considered to be because, as the distance D2 between the end surface of the transparent substrate 30 and the imaging region 12 of the solid-state imaging element 10 becomes longer, light reflected at the end surface of the transparent substrate becomes less likely to enter pixels.

From results of Examples 1 to 4 and Examples 5 to 6, when the distance D4 between the end surface of the transparent substrate 30 and the outer surface of the frame 40 is 150 μm or less, no bubbles were present under the eave of the transparent substrate 30 outside the frame 40, and the potting resin 60 was filled up to under the eave of the transparent substrate 30 outside the frame 40.

From results of Examples 1 to 2 and Examples 3 to 6, when the distance D4 between the end surface of the transparent substrate 30 and the outer surface of the frame 40 is 75 μm or less, no contact between the wiring 22 and the transparent substrate 30 was observed.

From results of Examples 3 to 4 and Examples 7 to 9, when an edge of the transparent substrate 30 was processed, no contact between the wiring 22 and the transparent substrate 30 was observed.

From results of Example 3 and Example 10, when a color of the frame 40 is black, frame-derived flare can be suppressed.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### EXPLANATION OF REFERENCE NUMERALS

1, 1A, 1B, 1C, 1X, 1Y: solid-state imaging device
10, 10X: solid-state imaging element
15: solid-state imaging element mounted on wiring substrate
12: imaging region
20: wiring substrate
22: wiring
24: conductive member
25: electrode
30, 30A, 30B, 30X, 30Y: transparent substrate
35: transparent substrate with frame
35A: first laminate
35B: second laminate
40, 40X: frame
60: resin

1. A solid-state imaging device, comprising:
a solid-state imaging element;
a transparent substrate that faces the solid-state imaging element; and
a frame, disposed between the solid-state imaging element and the transparent substrate, that surrounds an imaging region of the solid-state imaging element, wherein
a distance between an end surface of the solid-state imaging element and the imaging region of the solid-state imaging element is 650 μm or less, and
a distance between an end surface of the transparent substrate and the imaging region of the solid-state imaging element is 375 μm or more.

2. The solid-state imaging device according to claim 1, wherein a distance between the end surface of the transparent substrate and an outer surface of the frame is 50 μm or more.

3. The solid-state imaging device according to claim 2, wherein
the distance between the end surface of the transparent substrate and the outer surface of the frame is 50 μm or more and 300 μm or less, and
the distance between the end surface of the transparent substrate and the imaging region of the solid-state imaging element is 375 μm or more and 625 μm or less.

4. The solid-state imaging device according to claim 1, wherein the transparent substrate includes a notch at a peripheral corner portion on a side facing the solid-state imaging element.

5. The solid-state imaging device according to claim 1, wherein a resin composition of the frame includes a colorant.
